(19) United States
(12) Patent Application Publication
(10) Pub. No.: US 2017/0074822 A1
(43) Pub. Date: Mar. 16, 2017

(54) ELECTROCHEMICAL SENSOR

(71) Applicant: Kabushiki Kaisha Toshiba, Minato-ku (JP)

(72) Inventors: Kazuya MATSUZAWA, Kamakura (JP); Keiji IKEDA, Kawasaki (JP); Tsutomu TEZUKA, Yokohama (JP)

(73) Assignee: Kabushiki Kaisha Toshiba, Minato-ku (JP)

(21) Appl. No.: 15/235,421

(22) Filed: Aug. 12, 2016

(30) Foreign Application Priority Data
Sep. 11, 2015 (JP) 2015-179374

(51) Int. Cl. G01N 27/414; H01L 29/792

(52) U.S. Cl. CPC G01N 27/4148; H01L 29/792

(57) ABSTRACT

An electrochemical sensor according to an embodiment, includes a first insulating film, an electrode, a semiconductor layer provided between the first insulating film and the electrode, and a charge storage layer provided between the electrode and the semiconductor layer.

### CROSS-REFERENCE TO RELATED APPLICATION

This application is based upon and claims the benefit of priority from Japanese Patent Application No. 2015-179374, filed on Sep. 11, 2015, the entire contents of which are incorporated herein by reference.

### FIELD

Embodiments described herein relate generally to an electrochemical sensor.

### BACKGROUND

An ion sensitive field effect transistor (hereinafter, referred to as an “ISFET”) is one of electrochemical sensors used for measuring a pH level, a blood sugar level in blood. The ISFET is a transistor including an ion sensitive membrane.

An ISFET of the related art has a structure in which a metal gate film of metal oxide semiconductor field effect transistor (MOSFET) is replaced with an ion sensitive membrane. The ion sensitive membrane directly comes in contact with a sample solution. Gate potential is applied from a reference electrode through the solution.

There is a risk that a threshold voltage of the ISFET varies due to a process variation in manufacturing the ISFET. A threshold voltage of the ISFET is sometimes required to be optimized in order to secure a measuring range for every type of target object to be measured. Accordingly, an electrochemical sensor capable of adjusting the threshold voltage of the ISFET is required.

### BRIEF DESCRIPTION OF THE DRAWINGS

FIG. 1 is a schematic view of a sensor of an electrochemical sensor according to a first embodiment;

FIG. 2 is a schematic view of a sensor of an electrochemical sensor according to a second embodiment;

FIG. 3 is a schematic view of a sensor of an electrochemical sensor according to a third embodiment;

FIG. 4 is a schematic view of a sensor of an electrochemical sensor according to a fourth embodiment;

FIG. 5 is an equivalent circuit diagram of transistors in the sensor according to the fourth embodiment;

FIG. 6 is a graphical representation for describing a function and an effect of the electrochemical sensor according to the fourth embodiment;

FIG. 7 is a schematic view of a sensor of an electrochemical sensor according to a fifth embodiment;

FIG. 8 is a schematic view of a sensor of an electrochemical sensor according to a sixth embodiment;

FIG. 9 is a schematic view of a sensor of an electrochemical sensor according to a seventh embodiment;

FIG. 10 is a schematic view of an electrochemical sensor according to an eighth embodiment; and

FIG. 11 is a schematic view of an electrochemical sensor according to a ninth embodiment.

### DETAILED DESCRIPTION

An electrochemical sensor according to an embodiment includes a first insulating film, an electrode, a semiconductor layer provided between the first insulating film and the electrode, and a charge storage layer provided between the electrode and the semiconductor layer.

### First Embodiment

The electrochemical sensor according to the present embodiment includes the first insulating film, the electrode, the semiconductor layer provided between the first insulating film and the electrode, and the charge storage layer provided between the electrode and the semiconductor layer.

The electrochemical sensor according to the present embodiment is, for example, a pH sensor or an enzyme sensor. The electrochemical sensor according to the present embodiment includes, for example, a sensor, a detecting circuit, and a control circuit. The sensor converts, for example, a pH level of a target object to be measured (target material) into an electrical signal. The detecting circuit amplifies, for example, the electrical signal acquired by the sensor. The control circuit controls, for example, operation of each of the sensor and the detecting circuit.

Note that, the target object to be measured T is, for example, an electrolyte including a solution and an enzyme.

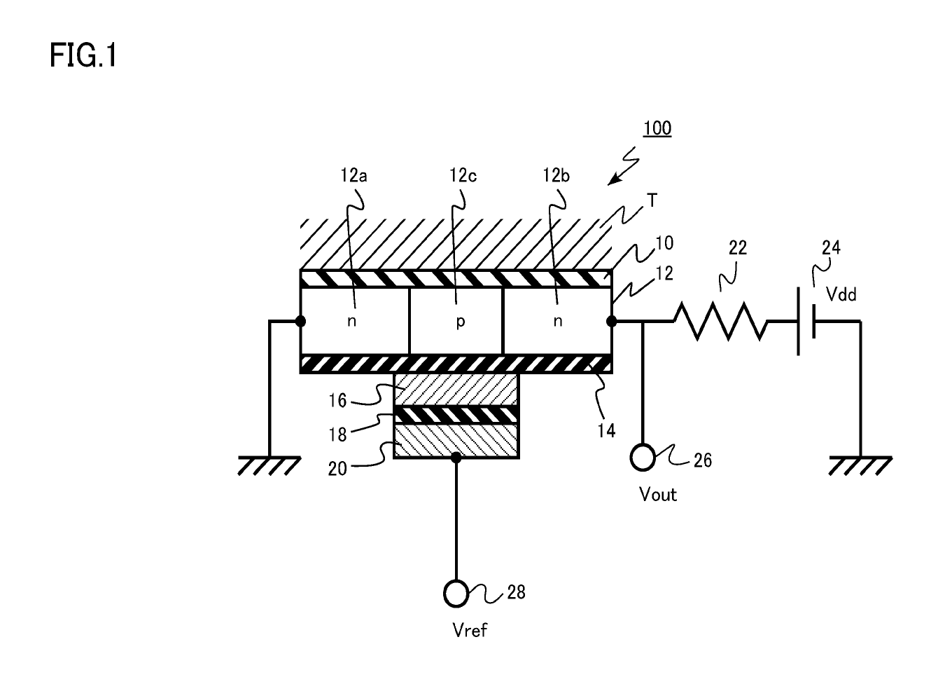

FIG. 1 is a schematic view of the sensor 100 of the electrochemical sensor according to the present embodiment. A transistor in the sensor 100 of the electrochemical sensor according to the present embodiment is an ISFET.

The sensor 100 includes the ion sensitive membrane (first insulating film) 10, the semiconductor layer 12, a tunnel insulating film (third insulating film) 14, the floating gate electrode (charge storage layer) 16, a block insulating film (second insulating film) 18, and the reference electrode (electrode) 20 that are included in the ISFET. The ISFET according to the present embodiment is an n-channel transistor in which an electron acts as a carrier.

The semiconductor layer 12 is provided between the ion sensitive membrane 10 and the reference electrode 20. The floating gate electrode 16 is provided between the semiconductor layer 12 and the reference electrode 20. The block insulating film 18 is provided between the reference electrode 20 and the floating gate electrode 16. The tunnel insulating film 14 is provided between the semiconductor layer 12 and the floating gate electrode 16.

The ion sensitive membrane 10 is provided in contact with the semiconductor layer 12. The ion sensitive membrane 10 selectively adsorbs a specific ion in the target object to be measured (“T” in FIG. 1). The ion sensitive membrane 10 is, for example, an inorganic insulating film or an organic insulating film.

The ion sensitive membrane 10 is, for example, a silicon nitride film, an aluminum oxide film, or a tantalum oxide film. The ion sensitive membrane 10 is also, for example, an enzyme immobilized membrane. The enzyme immobilized membrane is a polymer membrane.

The semiconductor layer 12 is, for example, single crystal silicon. The semiconductor layer 12 includes an n-type source region (first impurity region) 12a, an n-type drain region (second impurity region) 12b, and a p-type channel region (third impurity region) 12c. The p-type channel region 12c is provided between the n-type source region 12a and the n-type drain region 12b. The p-type channel region 12c is provided between the ion sensitive membrane 10 and the floating gate electrode 16.

The tunnel insulating film 14 is provided in contact with the semiconductor layer 12. The tunnel insulating film 14 has a function for electrically separating the semiconductor layer 12 and the floating gate electrode 16. The tunnel insulating film 14 is, for example, a silicon oxide film.

The floating gate electrode 16 is provided in contact with the tunnel insulating film 14. The floating gate electrode 16 has a function for storing an electric charge. The electric charge is, for example, an electron or a positive hole.

The floating gate electrode 16 is a conductive film. The floating gate electrode 16 is, for example, polycrystalline silicon doped with conductive impurity.

The block insulating film 18 is provided in contact with the floating gate electrode 16. The block insulating film 18 has a function for electrically separating the floating gate electrode 16 and the reference electrode 20. The block insulating film 18 is, for example, a silicon oxide film. The block insulating film 18 is, for example, a High-k insulating film (high dielectric constant insulating film), such as an aluminum oxide film or a hafnium oxide film.

The reference electrode 20 is provided in contact with the block insulating film 18. A reference voltage (Vref) is applied to the reference electrode 20 when the target object to be measured T is measured. A desired voltage is also applied to the reference electrode 20 when the electric charge is stored in the floating gate electrode 16 or the electric charge is erased from the floating gate electrode 16.

The reference electrode 20 is a conductive film. The reference electrode 20 is, for example, polycrystalline silicon doped with conductive impurity. The reference electrode 20 is, for example, a metal or a metal semiconductor compound.

The n-type source region 12a is, for example, fixed to ground potential. The n-type drain region 12b is, for example, coupled to a resistor 22 and a power source 24. A power source voltage (Vdd) is applied from the power source 24. Note that, potential of the n-type source region 12a is at least distally lower than the power source voltage (Vdd).

The n-type drain region 12b is coupled to an output terminal 26. An output signal (Vout) is output from the output terminal 26.

The reference electrode 20 is coupled to a reference terminal 28. For example, the reference voltage (Vref) is applied to the reference terminal 28.

A function and an effect of the electrochemical sensor according to the present embodiment will be described below.

There is a risk that a threshold voltage of the ISFET varies due to a process variation in manufacturing the ISFET. A threshold voltage of the ISFET is sometimes required to be optimized in order to secure a measuring range in response to a type of target object to be measured T.

In the electrochemical sensor according to the present embodiment, the ISFET in the sensor 100 includes the floating gate electrode 16. Because the ISFET includes the floating gate electrode 16, the threshold voltage of the ISFET can be adjusted.

For example, a positive voltage is applied between the reference electrode 20 and the semiconductor layer 12. Accordingly, a tunnel current flowing through the tunnel insulating film 14 injects the electron from the semiconductor layer 12 to the floating gate electrode 16. Writing of the electron increases the threshold voltage of the n-channel ISFET.

Changing an injection condition of the electric charge into the floating gate electrode 16 can determine the threshold voltage to be a desired target value.

Therefore, the variation in the threshold voltage due to the process variation in manufacturing the ISFET can be corrected. The threshold voltage of the ISFET can be optimized in order to secure the measuring range in response to the type of target object to be measured T.

In the ISFET according to the present embodiment, the ion sensitive membrane 10 is provided on the side of a back surface of the semiconductor layer 12. The side on which the reference electrode 20 is present with respect to the semiconductor layer 12 is defined as the side of a surface. For example, the ion sensitive membrane 10 adsorbs a particular ion in the target object to be measured T. Thus, potential of the p-type channel region 12c varies. In other words, substrate potential of the ISFET varies. The ISFET according to the present embodiment detects, as the output signal (Vout), a variation of a drain voltage in accordance with the variation of the substrate potential.

In the ISFET according to the present embodiment, the ion sensitive membrane 10 is provided on the side of the back surface of the semiconductor layer 12. Thus, a distance between the reference electrode 20 and the floating gate electrode 16 and a distance between the reference electrode 20 and the semiconductor layer 12 can be shortened. Therefore, scaling-down and integration of the ISFET can be realized. Thus, scaling-down and integration of the sensor 100 and the electrochemical sensor can be realized.

According to the electrochemical sensor of the present embodiment, the threshold voltage of the ISFET can be adjusted. The scaling-down and the integration of the ISFET can be also realized.

### Second Embodiment

An electrochemical sensor according to the present embodiment is different from that according to the first embodiment in that a charge storage layer is an insulating film. Therefore, the descriptions of details that duplicate with respect to the first embodiment will be omitted.

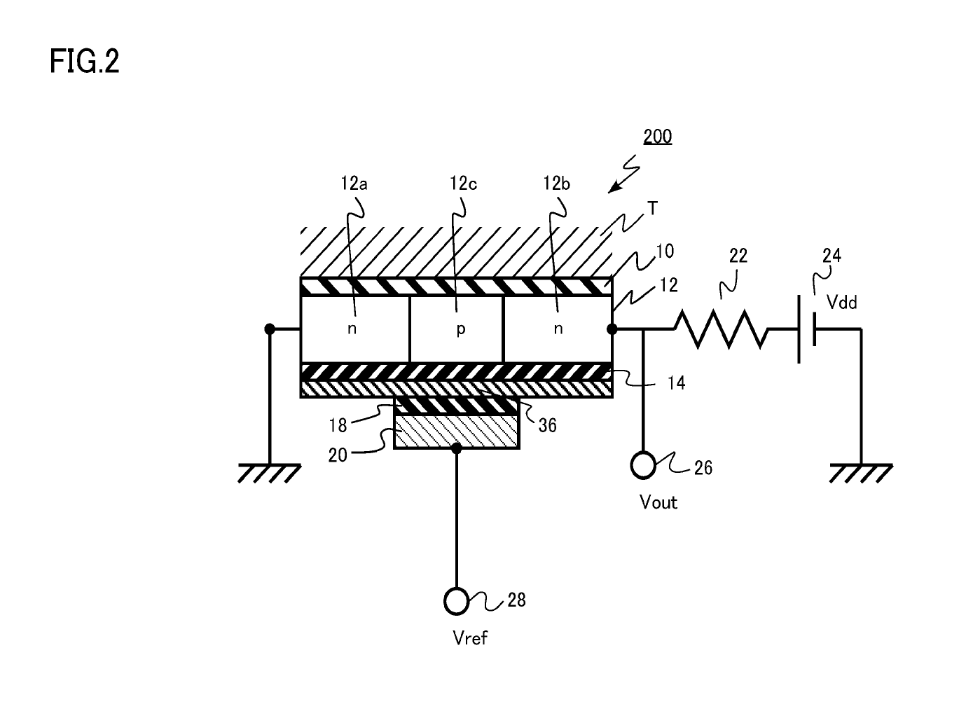

FIG. 2 is a schematic view of a sensor 200 of the electrochemical sensor according to the present embodiment. A transistor in the sensor 200 of the electrochemical sensor according to the present embodiment is an ISFET.

The sensor 200 includes an ion sensitive membrane (first insulating film) 10, a semiconductor layer 12, a tunnel insulating film (third insulating film) 14, the charge storage insulating film (charge storage layer) 36, a block insulating film (second insulating film) 18, and a reference electrode (electrode) 20 that are included in the ISFET. The ISFET according to the present embodiment is an n-channel transistor in which an electron acts as a carrier.

The charge storage insulating film 36 is provided in contact with the tunnel insulating film 14. The charge storage insulating film 36 is also provided in contact with the block insulating film 18.

The charge storage insulating film 36 has a function for storing an electric charge. The electric charge is, for example, an electron or a positive hole. The charge storage insulating film 36 is an insulating film. The charge storage insulating film 36 is, for example, a silicon nitride film.

The ISFET according to the present embodiment includes the so-called metal oxide nitride oxide silicon (MONOS) structure.

The electrochemical sensor according to the present embodiment can adjust a threshold voltage of the ISFET, similarly to the first embodiment. Scaling-down and integration of the ISFET can be also realized.

Furthermore, the charge storage layer can be thinned. Thus, further scaling-down and integration of the ISFET can be realized. There is no need for patterning of the charge storage layer. Thus, the ISFET is easy to manufacture.

### Third Embodiment

An electrochemical sensor according to the present embodiment is different from that according to the first embodiment in that a first impurity region and a second impurity region are not provided on the side of a back surface of a semiconductor layer 12. Therefore, the descriptions of details that duplicate with respect to the first embodiment will be omitted.

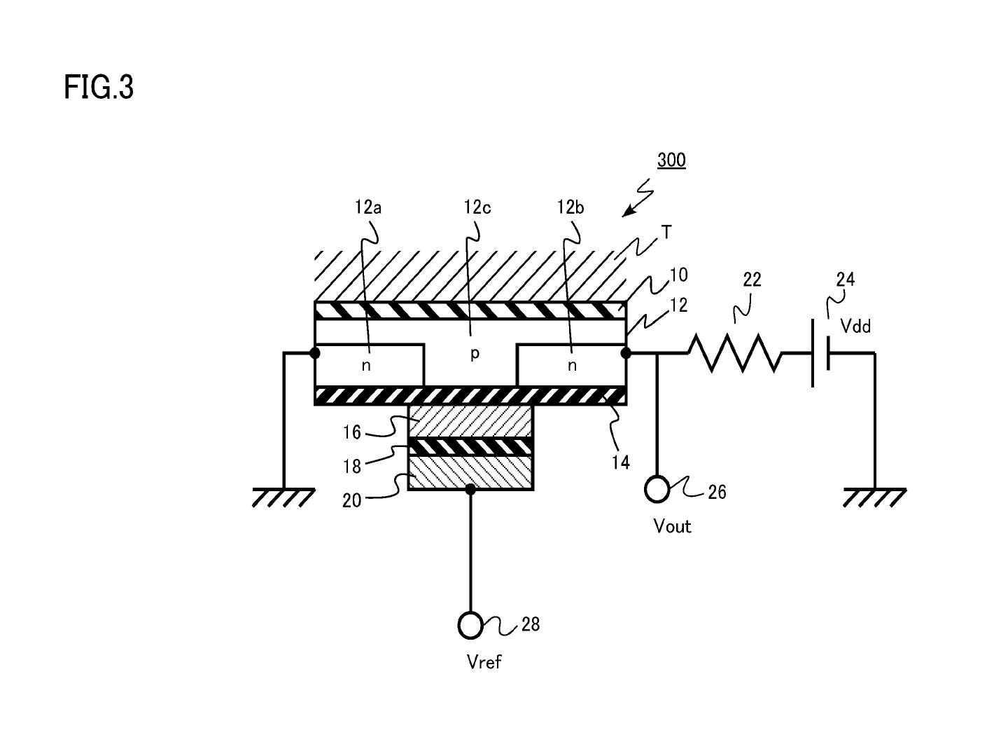

FIG. 3 is a schematic view of a sensor 300 of the electrochemical sensor according to the present embodiment. A transistor in the sensor 300 of the electrochemical sensor according to the present embodiment is an ISFET.

The sensor 300 includes an ion sensitive membrane (first insulating film) 10, the semiconductor layer 12, a tunnel insulating film (third insulating film) 14, a floating gate electrode (charge storage layer) 16, a block insulating film (second insulating film) 18, and a reference electrode (electrode) 20 that are included in the ISFET. The ISFET according to the present embodiment is an n-channel transistor in which an electron acts as a carrier.

The semiconductor layer 12 is, for example, single crystal silicon. The semiconductor layer 12 includes the n-type source region (first impurity region) 12a, the n-type drain region (second impurity region) 12b, and a p-type channel region (third impurity region) 12c. The p-type channel region 12c is provided between the n-type source region 12a and the n-type drain region 12b.

The n-type source region 12a and the n-type drain region 12b are not provided on the side of the back surface of the semiconductor layer 12. In other words, the p-type channel region 12c is not completely surrounded by the n-type source region 12a and the n-type drain region 12b.

The electrochemical sensor according to the present embodiment can adjust a threshold voltage of the ISFET, similarly to the first embodiment. The scaling-down and the integration of the ISFET can be also realized.

Furthermore, a voltage is easily applied to the p-type channel region 12c. Thus, an electric charge is easily written into the charge storage layer and the electric charge is easily erased from the charge storage layer.

### Fourth Embodiment

An electrochemical sensor according to the present embodiment, includes a first insulating film, a first electrode, a second electrode, a semiconductor layer provided between the first insulating film and the first electrode and between the first insulating film and the second electrode, a first charge storage layer provided between the first electrode and the semiconductor layer, and a second charge storage layer provided between the second electrode and the semiconductor layer.

The electrochemical sensor according to the present embodiment is different from that according to the first embodiment in that two ISFETs are coupled in series as transistors in a sensor. The descriptions of details that duplicate with respect to the first embodiment will be partially omitted below.

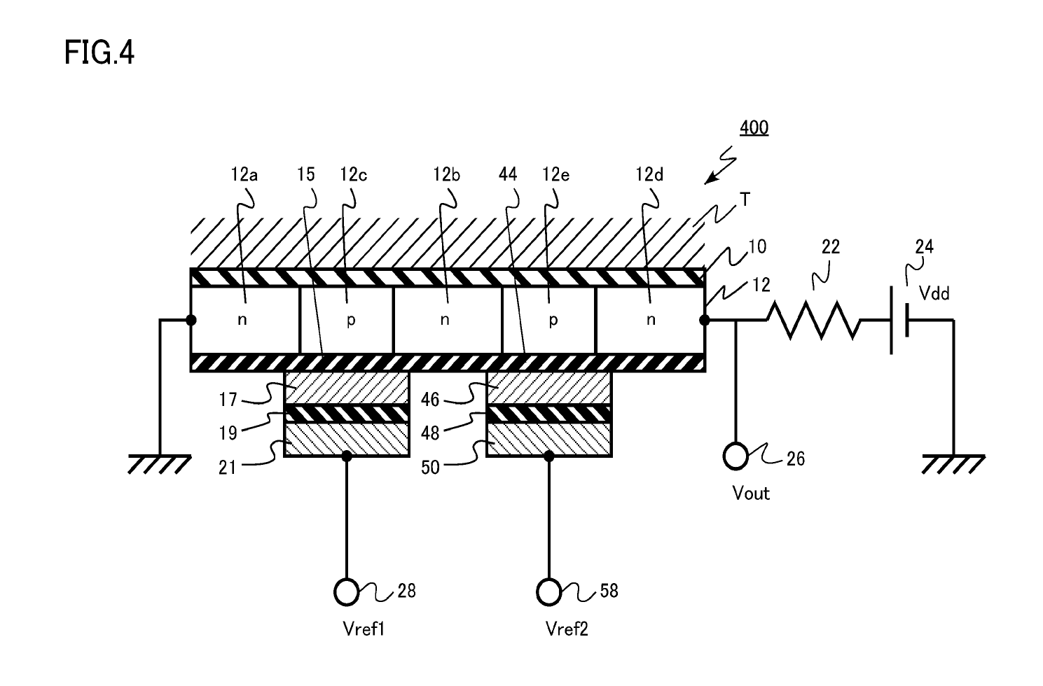

FIG. 4 is a schematic view of the sensor 400 of the electrochemical sensor according to the present embodiment. The sensor 400 of the electrochemical sensor according to the present embodiment includes the two ISFETs.

The sensor 400 includes the ion sensitive membrane (first insulating film) 10, the semiconductor layer 12, a first tunnel insulating film (fourth insulating film) 15, the first floating gate electrode (first charge storage layer) 17, a first block insulating film (second insulating film) 19, the first reference electrode (first electrode) 21, a second tunnel insulating film (fifth insulating film) 44, the second floating gate electrode (second charge storage layer) 46, a second block insulating film (third insulating film) 48, and the second reference electrode (second electrode) 50 that are included in the ISFETs. The ISFET according to the present embodiment is an n-channel transistor in which an electron acts as a carrier.

The semiconductor layer 12 is provided between the ion sensitive membrane 10 and the first reference electrode 21. The first floating gate electrode 17 is provided between the semiconductor layer 12 and the first reference electrode 21. The first block insulating film 19 is provided between the first reference electrode 21 and the first floating gate electrode 17. The first tunnel insulating film 15 is provided between the semiconductor layer 12 and the first floating gate electrode 17.

The semiconductor layer 12 is provided between the ion sensitive membrane 10 and the second reference electrode 50. The second floating gate electrode 46 is provided between the semiconductor layer 12 and the second reference electrode 50. The second block insulating film 48 is provided between the second reference electrode 50 and the second floating gate electrode 46. The second tunnel insulating film 44 is provided between the semiconductor layer 12 and the second floating gate electrode 46.

The semiconductor layer 12 is, for example, single crystal silicon. The semiconductor layer 12 includes an n-type source region (first impurity region) 12a, a first n-type drain region (second impurity region) 12b, and a first p-type channel region (third impurity region) 12c. The first p-type channel region 12c is provided between the n-type source region 12a and the first n-type drain region 12b. The first p-type channel region 12c is provided between the ion sensitive membrane 10 and the first floating gate electrode 17.

The semiconductor layer 12 also includes a second n-type drain region (fourth impurity region) 12d and a second p-type channel region (fifth impurity region) 12e. The second p-type channel region 12e is provided between the first n-type drain region 12b and the second n-type drain region 12d. The second p-type channel region 12e is provided between the ion sensitive membrane 10 and the second floating gate electrode 46.

Note that, the first tunnel insulating film 15 and the second tunnel insulating film 44 are simultaneously formed.

The n-type source region 12a is, for example, fixed to ground potential. The second n-type drain region 12d is, for example, coupled to a resistor 22 and a power source 24. A power source voltage (Vdd) is applied from the power source 24.

The second n-type drain region 12d is coupled to an output terminal 26. An output signal (Vout) is output from the output terminal 26.

The first reference electrode 21 is coupled to a first reference terminal 28. For example, a first reference voltage (Vref1) is applied to the first reference terminal 28.

The second reference electrode 50 is coupled to a second reference terminal 58. For example, a second reference voltage (Vref2) is applied to the second reference terminal 58.

The first reference electrode 21 and the second reference electrode 50 are electrically separated from each other.

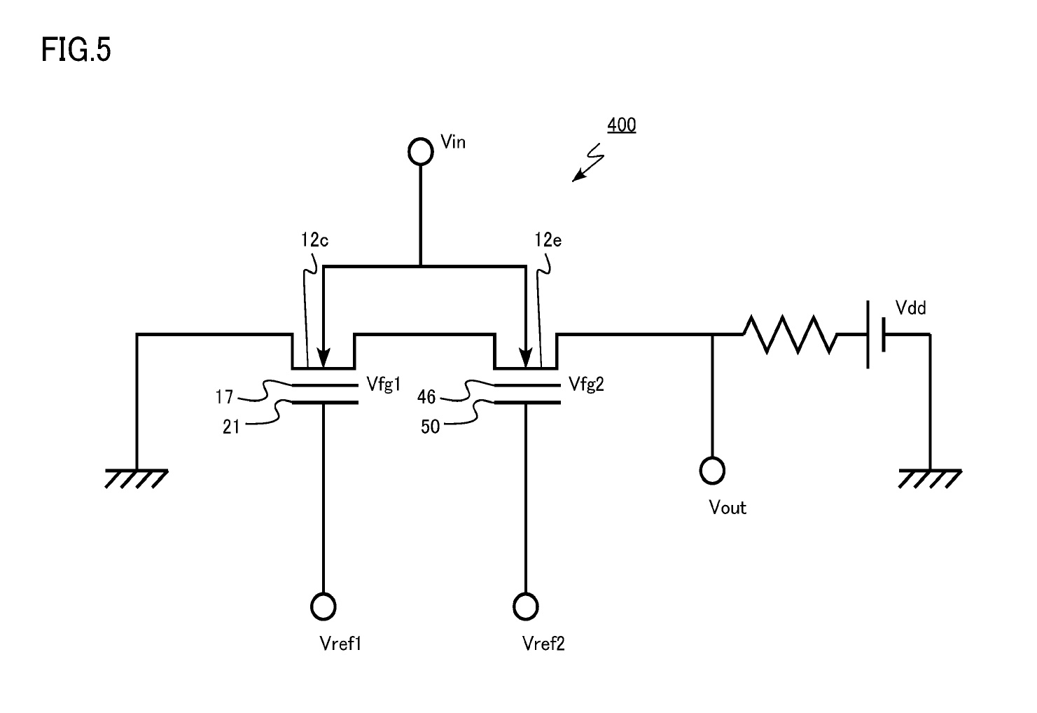

FIG. 5 is an equivalent circuit diagram of the transistors in the sensor according to the present embodiment.

As illustrated in FIG. 5, the two ISFETs are coupled in series. When a target object to be examined T is measured, an electric charge amount of the first floating gate electrode 17 and an electric charge amount of the second floating gate electrode 46 are adjusted so that a voltage (Vfg1) of the first floating gate electrode 17 and a voltage (Vfg2) of the second floating gate electrode 46 are satisfied with the following expression: Vfg1>Vfg2. Accordingly, a threshold voltage of the ISFET having the second floating gate electrode 46 becomes higher than a threshold voltage of the ISFET having the first floating gate electrode 17.

When the target object to be examined T is measured, the first reference voltage (Vref1) and the second reference voltage (Vref2) are made to be equivalent to each other.

A voltage to be applied to the first p-type channel region 12c and the second p-type channel region 12e becomes an input voltage (Vin) due to the target object to be measured T.

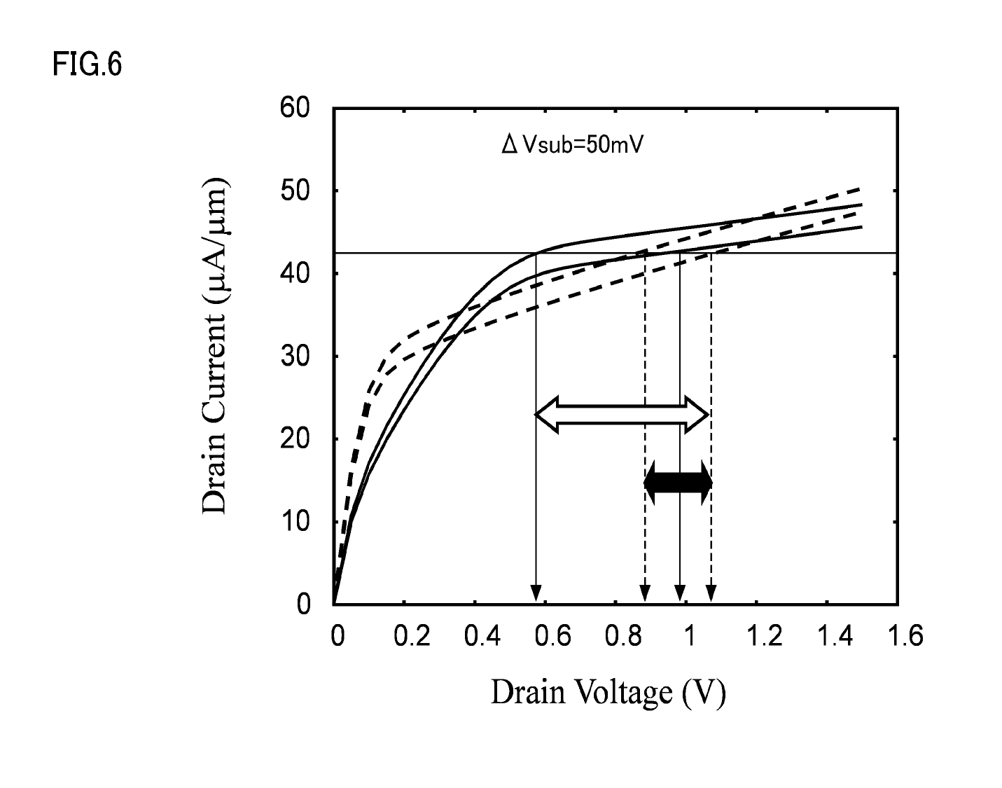

FIG. 6 is a graphical representation for describing a function and an effect of the electrochemical sensor according to the present embodiment. A simulation result of operating characteristics of the transistors in the sensor 400 according to the present embodiment, namely, the transistors including the ISFETs coupled in series, is illustrated.

A horizontal axis represents drain voltage and a vertical axis represents drain current. Current-voltage characteristics are indicated with a solid line in a case where the following expression is satisfied: Vfg1>Vfg2. Current-voltage characteristics are indicated with a broken line in a case where the following expression is satisfied: Vfg1=Vfg2. The current-voltage characteristics in each of the cases include a substrate voltage (Vsub) of 50 mV.

A double-pointed white arrow in the figure indicates an output voltage variation in the case where the following expression is satisfied: Vfg1>Vfg2. A double-pointed black arrow in the figure indicates an output voltage variation in the case where the following expression is satisfied: Vfg1=Vfg2. The output voltage variation is larger in the case where the following expression is satisfied: Vfg1>Vfg2. That is, measurement sensitivity in the case where the following expression is satisfied: Vfg1>Vfg2 improves in comparison to the case where the following expression is satisfied: Vfg1=Vfg2.

The electrochemical sensor according to the present embodiment can adjust a threshold voltage of each of the ISFETs, similarly to the first embodiment. Scaling-down and integration of the ISFETs can be also realized.

Furthermore, the electrochemical sensor according to the present embodiment writes an electric charge in each of the charge storage layers in a predetermined condition. Thus, the measurement sensitivity improves.

### Fifth Embodiment

An electrochemical sensor according to the present embodiment is different from that according to the fourth embodiment in that charge storage layers are insulating films. Therefore, the descriptions of details that duplicate with respect to the fourth embodiment will be omitted.

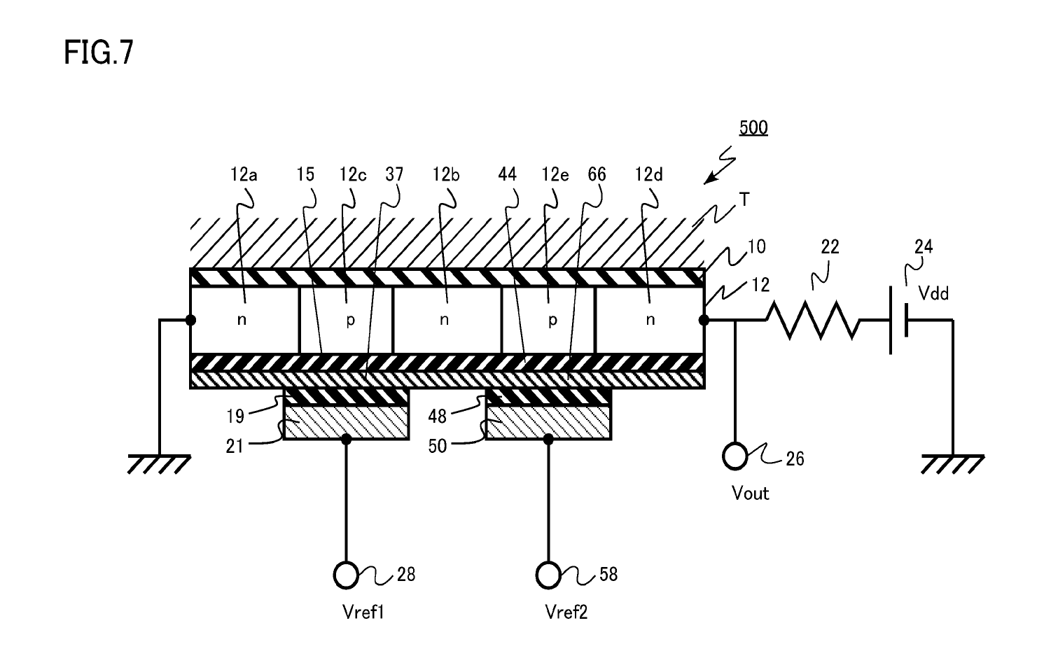

FIG. 7 is a schematic view of a sensor 500 of the electrochemical sensor according to the present embodiment. The sensor 500 of the electrochemical sensor according to the present embodiment includes two ISFETs.

The sensor 500 includes anion sensitive membrane (first insulating film) 10, a semiconductor layer 12, a first tunnel insulating film (fourth insulating film) 15, the first charge storage insulating film (first charge storage layer) 37, a first block insulating film (second insulating film) 19, a first reference electrode (first electrode) 21, a second tunnel insulating film (fifth insulating film) 44, the second charge storage insulating film (second charge storage layer) 66, a second block insulating film (third insulating film) 48, and a second reference electrode (second electrode) 50 that are included in the ISFETs. Each of the ISFETs according to the present embodiment is an n-channel transistor in which an electron acts as a carrier.

The semiconductor layer 12 is provided between the ion sensitive membrane 10 and the first reference electrode 21. The first charge storage insulating film 37 is provided between the semiconductor layer 12 and the first reference electrode 21. The first block insulating film 19 is provided between the first reference electrode 21 and the first charge storage insulating film 37. The first tunnel insulating film 15 is provided between the semiconductor layer 12 and the first charge storage insulating film 37.

The semiconductor layer 12 is provided between the ion sensitive membrane 10 and the second reference electrode 50. The second charge storage insulating film 66 is provided between the semiconductor layer 12 and the second reference electrode 50. The second block insulating film 48 is provided between the second reference electrode 50 and the second charge storage insulating film 66. The second tunnel insulating film 44 is provided between the semiconductor layer 12 and the second charge storage insulating film 66.

The first charge storage insulating film 37 is provided in contact with the first tunnel insulating film 15. The first charge storage insulating film 37 is provided in contact with the first block insulating film 19.

The first charge storage insulating film 37 has a function for storing an electric charge. The electric charge is, for example, an electron or a positive hole. The first charge storage insulating film 37 is an insulating film. The first charge storage insulating film 37 is, for example, a silicon nitride film.

The second charge storage insulating film 66 is provided in contact with the second tunnel insulating film 44. The second charge storage insulating film 66 is provided in contact with the second block insulating film 48.

The second charge storage insulating film 66 has a function for storing an electric charge. The electric charge is, for example, an electron or a positive hole. The second charge storage insulating film 66 is an insulating film. The second charge storage insulating film 66 is, for example, a silicon nitride film.

Note that, the first charge storage insulating film 37 and the second charge storage insulating film 66 are simultaneously formed.

Each of the ISFETs according to the present embodiment includes the so-called metal oxide nitride oxide silicon (MONOS) structure.

The electrochemical sensor according to the present embodiment can adjust a threshold voltage of each of the ISFETs, similarly to the fourth embodiment. The scaling-down and the integration of the ISFET can be also realized. The electric charge is written in each of the charge storage layers in a predetermined condition. Thus, measurement sensitivity improves.

Furthermore, the charge storage layers can be thinned. Thus, further scaling-down and integration of the ISFETs can be realized. There is no need for patterning of the charge storage layers. Thus, the ISFETs are easy to manufacture.

### Sixth Embodiment

An electrochemical sensor according to the present embodiment is different from that according to the fourth embodiment in that a first electrode and a second electrode are electrically coupled to each other. Therefore, the descriptions of details that duplicate with respect to the fourth embodiment will be omitted.

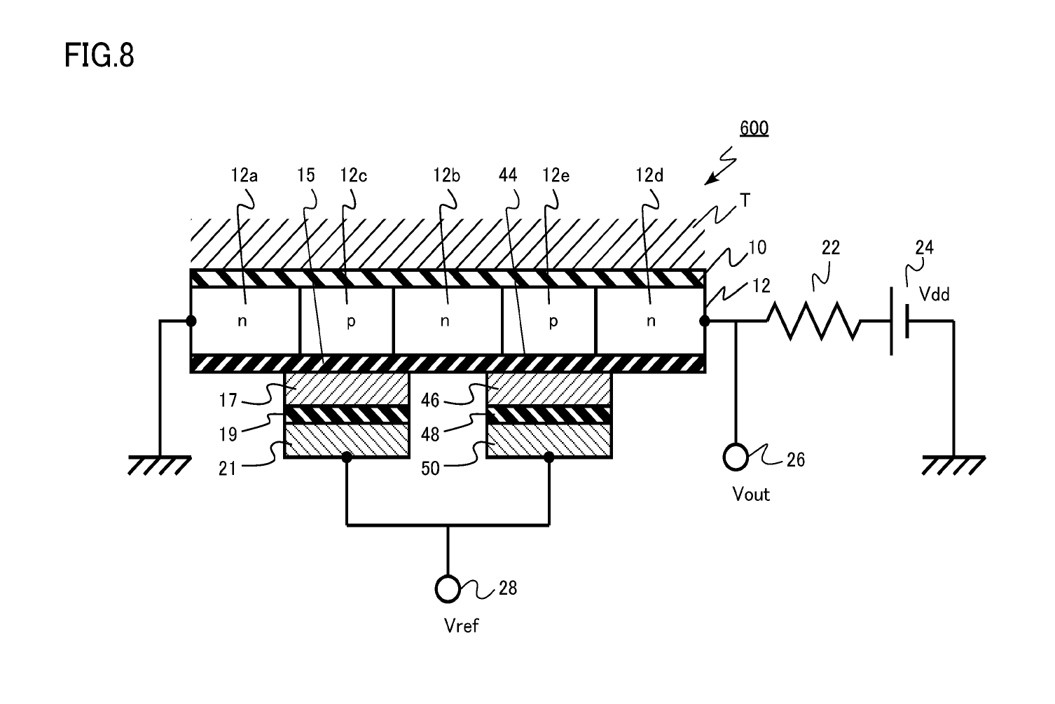

FIG. 8 is a schematic view of a sensor 600 of the electrochemical sensor according to the present embodiment. The sensor 600 of the electrochemical sensor according to the present embodiment includes two ISFETs.

The first reference electrode (first electrode) 21 and the second reference electrode (second electrode) 50 are electrically coupled to each other. The first reference electrode 21 and the second reference electrode 50 are coupled to a reference terminal 28.

The first reference electrode 21 and the second reference electrode 50 are electrically coupled to each other. Thus, a circuit configuration, such as a control circuit for reference voltage, is made to be simple.

A voltage (Vfg1) of a first floating gate electrode 17 and a voltage (Vfg2) of a second floating gate electrode 46 are adjusted so as to be different from each other, for example, as follows:

In a case where a tunnel current performs writing in the first floating gate electrode 17, a writing voltage is applied to the reference terminal 28. Next, a left power source voltage is made to be a low level and a right power source voltage is made to be the writing voltage or an open in FIG. 8.

In a case where a tunnel current performs writing in the second floating gate electrode 46, a writing voltage is applied to the reference terminal 28. Next, the right power source voltage is made to be the low level and the left power source voltage is made to be the writing voltage or the open in FIG. 8.

In a case where a thermoelectron performs writing in the first floating gate electrode 17, a writing voltage is applied to the reference terminal 28. Next, the left power source voltage is made to be a high level and the right power source voltage is made to be the low level in FIG. 8.

In a case where a thermoelectron performs writing in the second floating gate electrode 46, a writing voltage is applied to the reference terminal 28. Next, the right power source voltage is made to be the high level and the left power source voltage is made to be the low level in FIG. 8.

Note that erasing is collectively performed.

The electrochemical sensor according to the present embodiment can adjust a threshold voltage of each of the ISFETs, similarly to the fourth embodiment. The scaling-down and the integration of the ISFET can be also realized. An electric charge is written in each of the charge storage layers in a predetermined condition. Thus, measurement sensitivity improves.

Furthermore, a circuit configuration can be made to be simple.

### Seventh Embodiment

An electrochemical sensor according to the present embodiment is different from that according to the fourth embodiment in that a fourth impurity region and a fifth impurity region are not provided. The descriptions of details that duplicate with respect to the fourth embodiment will be omitted below.

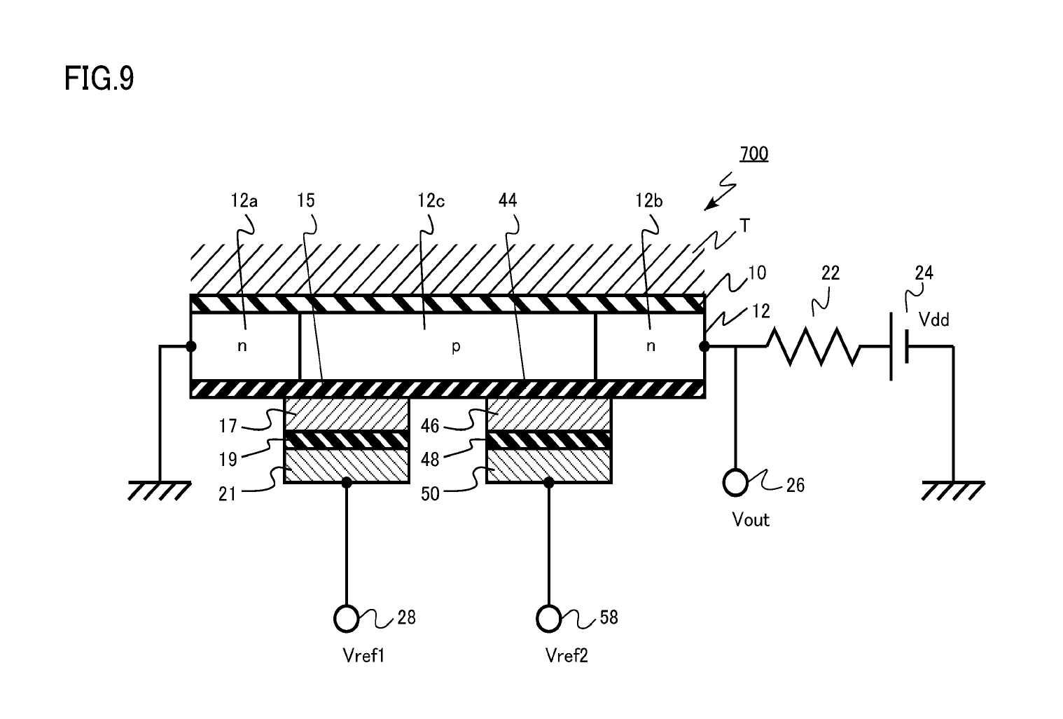

FIG. 9 is a schematic view of a sensor 700 of the electrochemical sensor according to the present embodiment. The sensor 700 of the electrochemical sensor according to the present embodiment includes two ISFETs.

A semiconductor layer 12 includes an n-type source region (first impurity region) 12a, an n-type drain region (second impurity region) 12b, and a p-type channel region (third impurity region) 12c. The p-type channel region 12c is provided between the n-type source region 12a and the n-type drain region 12b.

The p-type channel region 12c is provided between an ion sensitive membrane 10 and a first floating gate electrode 17 and between the ion sensitive membrane 10 and a second floating gate electrode 46.

In other words, an n-type impurity region is not present in the semiconductor layer 12 between the two ISFETs coupled in series. Since the n-type impurity region is not present, driving force of the transistors improves. Therefore, measurement sensitivity of the electrochemical sensor further improves.

The electrochemical sensor according to the present embodiment can adjust a threshold voltage of each of the ISFETs, similarly to the fourth embodiment. The scaling-down and the integration of the ISFET can be also realized. An electric charge is written in each of the charge storage layers in a predetermined condition. Thus, the measurement sensitivity improves.

In addition, the measurement sensitivity of the electrochemical sensor further improves due to the improvement of the driving force of the transistors.

### Eighth Embodiment

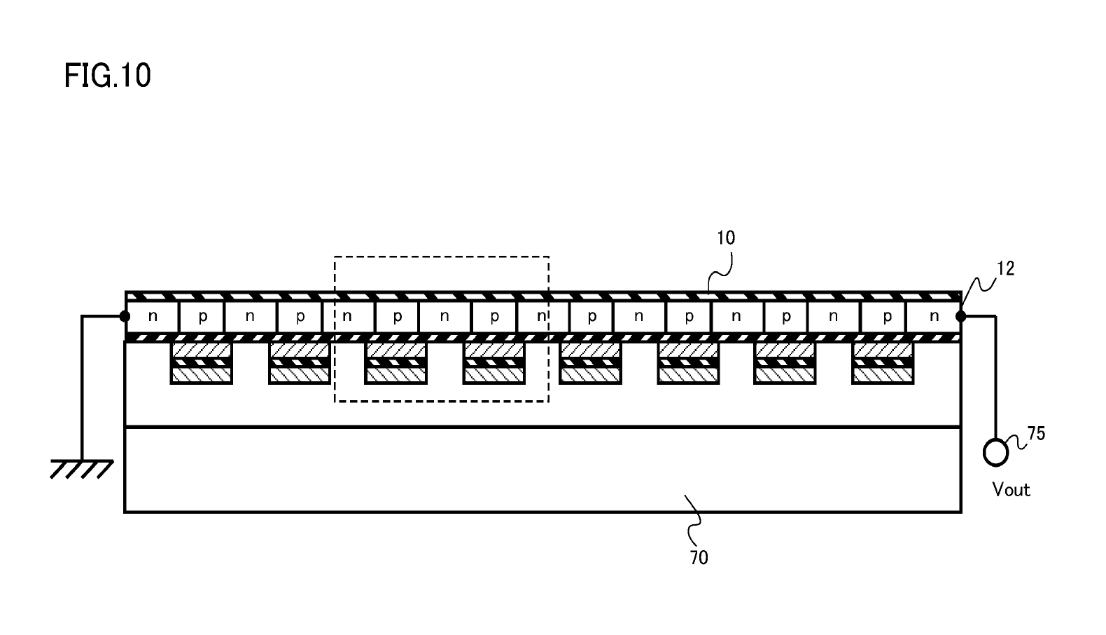

FIG. 10 is a schematic view of an electrochemical sensor according to the present embodiment. The electrochemical sensor according to the present embodiment includes a plurality of the transistors in the sensor 400 according to the fourth embodiment, coupled in series.

In FIG. 10, a region surrounded with a broken line corresponds to the transistors in the sensor 400 according to the fourth embodiment.

A source region of a transistor at one end in the plurality of the transistors coupled in series is, for example, fixed to ground potential. A drain region of a transistor at the other end in the plurality of the transistors is coupled to an output terminal 75. An output signal (Vout) is output from the output terminal 75.

A peripheral circuit 70 is provided on the side of reference electrodes of the transistors. Examples of the peripheral circuit 70 include a detecting circuit and a control circuit.

The electrochemical sensor according to the present embodiment can adjust a threshold voltage of each of the ISFETs, similarly to the fourth embodiment. The scaling-down and the integration of the ISFET can be also realized. The electric charge is written in each of the charge storage layers in a predetermined condition. Thus, measurement sensitivity improves.

Furthermore, the plurality of the transistors is coupled in series. Thus, a distribution of electric charges and an amount of the electric charges on an ion sensitive membrane 10 can be measured.

The ion sensitive membrane 10 is provided on the side of a back surface of a semiconductor layer 12 for the ISFETs according to the present embodiment. Thus, the peripheral circuit 70 for controlling the plurality of the transistors is easy to form.

Note that, in FIG. 10, a case where the plurality of the transistors is coupled in a line has been exemplarily described. A plurality of transistors may be provided in a plurality of lines. Then, an electrochemical sensor that measures a distribution of electric charges and an amount of the electric charges in two dimensions can be formed.

### Ninth Embodiment

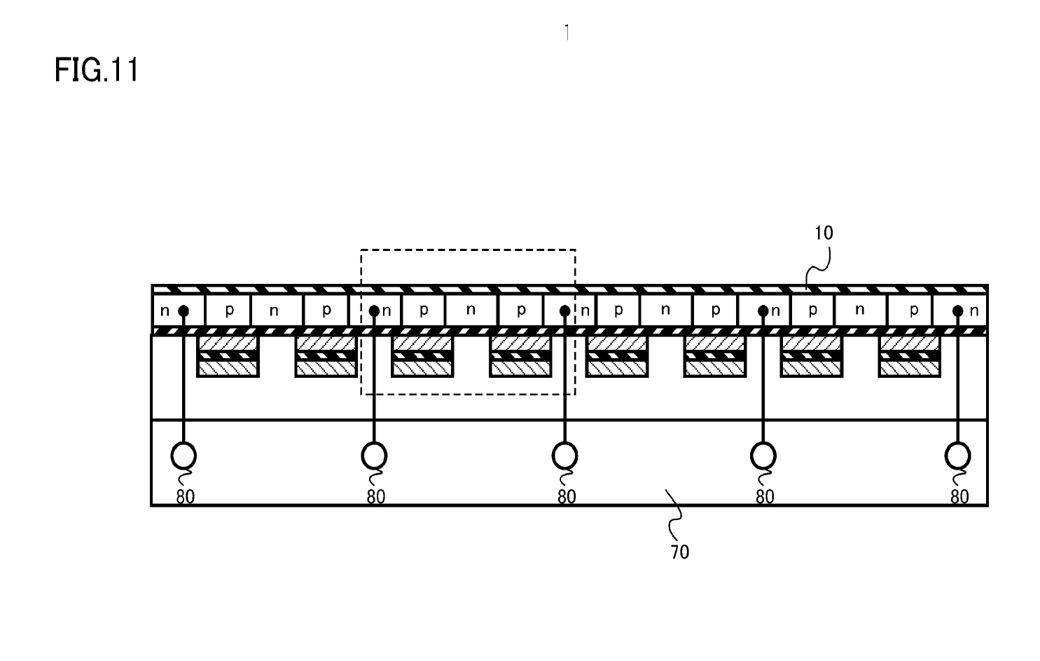

FIG. 11 is a schematic view of an electrochemical sensor according to the present embodiment. The electrochemical sensor according to the present embodiment includes a plurality of the transistors in the sensor 400 according to the fourth embodiment, coupled in series. The present embodiment is different from the eighth embodiment in that terminals are provided across each pair of transistors.

In FIG. 11, a region surrounded with a broken line corresponds to the transistors in the sensor 400 according to the fourth embodiment.

Each pair of transistors in the plurality of the transistors coupled in series includes the terminals 80 provided at both ends. For example, one of the terminals 80 at both of the ends of each pair of transistors is fixed to ground potential and the other is made to be an output terminal. For example, the terminal fixed to the ground potential and the output terminal are alternatively disposed.

A peripheral circuit 70 is provided on the side of reference electrodes of the transistors. Examples of the peripheral circuit 70 include a detecting circuit and a control circuit.

The electrochemical sensor according to the present embodiment can adjust a threshold voltage of each ISFET, similarly to the eighth embodiment. The scaling-down and the integration of the ISFET can be also realized. The electric charge is written in each of the charge storage layers in a predetermined condition. Thus, measurement sensitivity improves. A distribution of electric charges and an amount of the electric charges on an ion sensitive membrane 10 can be measured.

Furthermore, the terminals are provided at both of the ends of each pair of transistors in the plurality of the transistors. Thus, the distribution of the electric charges and the amount of the electric charges on the ion sensitive membrane 10 can be measured by each pair of transistors. Therefore, even in a case where an electric charge state of a target object to be measured T on the ion sensitive membrane 10 is unstable, the distribution of the electric charges and the amount of the electric charges on the ion sensitive membrane 10 can be measured. Time variations of both of the distribution of the electric charges and the amount of the electric charges on the ion sensitive membrane 10 can be also measured.

The ion sensitive membrane 10 is provided on the side of a back surface of a semiconductor layer 12 of the ISFETs according to the present embodiment. Thus, the peripheral circuit 70 for controlling the plurality of the transistors is easy to form.

Note that, in FIG. 11, a case where the plurality of the transistors is coupled in a line has been exemplarily described. A plurality of transistors may be provided in a plurality of lines. Then, an electrochemical sensor that measures a distribution of electric charges and an amount of the electric charges in two dimensions can be formed.

According to the first embodiment to the ninth embodiment, the pH sensor or the enzyme sensor has been described as an exemplary electrochemical sensor. The electrochemical sensor according to the present disclosure is not limited to the pH sensor or the enzyme sensor. For example, the present disclosure can be applied to various electrochemical sensors, such as a blood sugar level sensor, a cellular sensor, and a gas sensor.

According to the first embodiment to the ninth embodiment, a case where a first-conductivity type is n-type and a second-conductivity type is p-type, has been exemplarily described. The first-conductivity type may be p-type and the second-conductivity type maybe n-type. In this case, an ISFET becomes a p-channel transistor in which a positive hole acts as a carrier.

Note that, according to the third embodiment, the single ISFET has been described for the transistor in which the first impurity region and the second impurity region are not provided on the side of the back surface of the semiconductor layer 12. Two ISFETs of the third embodiment may be coupled in series so as to function similarly to the fourth embodiment. Furthermore, a plurality of the two ISFETs coupled in series according to the eighth embodiment and the ninth embodiment, may be coupled to each other and can be used.

While certain embodiments have been described, these embodiments have been presented by way of example only, and are not intended to limit the scope of the inventions. Indeed, an electrochemical sensor described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. An electrochemical sensor comprising:
a first insulating film;
an electrode;
a semiconductor layer provided between the first insulating film and the electrode; and
a charge storage layer provided between the electrode and the semiconductor layer.

2. The electrochemical sensor according to claim 1,
wherein the first insulating film is an ion sensitive membrane.

3. The electrochemical sensor according to claim 1,
wherein the semiconductor layer includes a first-conductivity type first impurity region, a first-conductivity type second impurity region, and a second-conductivity type third impurity region provided between the first impurity region and the second impurity region, and
the third impurity region is provided between the first insulating film and the charge storage layer.

4. The electrochemical sensor according to claim 1,
wherein the charge storage layer is a conductive film.

5. The electrochemical sensor according to claim 1,
wherein the charge storage layer is an insulating film.

6. The electrochemical sensor according to claim 1, further comprising a second insulating film provided between the electrode and the charge storage layer.

7. The electrochemical sensor according to claim 1, further comprising a third insulating film provided between the semiconductor layer and the charge storage layer.

8. An electrochemical sensor comprising:
a first insulating film;
a first electrode;
a second electrode;
a semiconductor layer provided between the first insulating film and the first electrode and between the first insulating film and the second electrode;
a first charge storage layer provided between the first electrode and the semiconductor layer; and
a second charge storage layer provided between the second electrode and the semiconductor layer.

9. The electrochemical sensor according to claim 8,
wherein the first insulating film is an ion sensitive membrane.

10. The electrochemical sensor according to claim 8,
wherein the semiconductor layer includes a first-conductivity type first impurity region, a first-conductivity type second impurity region, a second-conductivity type third impurity region provided between the first impurity region and the second impurity region, a first-conductivity type fourth impurity region, and a second-conductivity type fifth impurity region provided between the second impurity region and the fourth impurity region,
the third impurity region is provided between the first insulating film and the first charge storage layer, and
the fifth impurity region is provided between the first insulating film and the second charge storage layer.

11. The electrochemical sensor according to claim 8,
wherein the semiconductor layer includes a first-conductivity type first impurity region, a first-conductivity type second impurity region, and a second-conductivity type third impurity region provided between the first impurity region and the second impurity region, and
the third impurity region is provided between the first insulating film and the first charge storage layer and between the first insulating film and the second charge storage layer.

12. The electrochemical sensor according to claim 8,
wherein the first charge storage layer and the second charge storage layer are conductive films.

13. The electrochemical sensor according to claim 8,
wherein the first charge storage layer and the second charge storage layer are insulating films.

14. The electrochemical sensor according to claim 8, further comprising:
a second insulating film provided between the first electrode and the first charge storage layer; and
a third insulating film provided between the second electrode and the second charge storage layer.

15. The electrochemical sensor according to claim 8, further comprising:
a fourth insulating film provided between the semiconductor layer and the first charge storage layer; and
a fifth insulating film provided between the semiconductor layer and the second charge storage layer.

16. The electrochemical sensor according to claim 8,
wherein the first electrode and the second electrode are electrically separated from each other.

17. The electrochemical sensor according to claim 8,
wherein the first electrode and the second electrode are electrically coupled to each other.
